(19) United States
(12) Patent Application Publication
(10) Pub. No.: US 2025/0067886 A1
(43) Pub. Date: Feb. 27, 2025

(54) METHOD FOR PRODUCING A DETECTOR AND DETECTOR

(71) Applicant: KETEK GmbH Halbleiter-und Reinraumtechnik, Munchen (DE)

(72) Inventors: Lothar Höllt, Bad Heilbrunn (DE); Florian Dams, Regenstauf (DE); Sabrina Löbner, Germering (DE)

(21) Appl. No.: 18/452,994

(22) Filed: Aug. 21, 2023

(51) Int. Cl. G01T 1/24; H01L 31/115; H01L 31/18

(52) U.S. Cl. CPC G01T 1/244; H01L 31/115; H01L 31/1804

(57) ABSTRACT

In an embodiment a method includes providing a semiconductor body with a first main side and an opposite, second main side, wherein the semiconductor body is configured to detect radiation with an energy of at least 10 eV, and wherein the first main side includes a radiation entrance area for the radiation, generating a bottom insulation layer located directly at the first main side, the bottom insulation layer comprising a first electrically insulating material, applying a sacrificial layer directly on the bottom insulation layer across the entrance area so that throughout the entrance area the bottom insulation layer is between the semiconductor body and the sacrificial layer, applying a reinforcing layer over the bottom insulation layer so that the sacrificial layer is sandwiched between the bottom insulation layer and the reinforcing layer, the reinforcing layer comprising a second electrically insulating material and exposing the bottom insulation layer from the sacrificial layer and from the reinforcing layer in the entrance area.

### TECHNICAL FIELD

A method for producing a radiation detector is provided. Further, a corresponding radiation detector is provided.

### BACKGROUND

Patent Applications DE 103 08 626 A1 and U.S. 2020/0271599 A1 disclose radiation detectors.

### SUMMARY

Embodiments provide a radiation detector that has improved robustness.

According to at least one embodiment, the method comprises the step of providing a semiconductor body. For example, the semiconductor body is a silicon body. The semiconductor body comprises a first main side and an opposite, second main side. It is possible that the first and/or second main sides are of planar fashion and, thus, do not comprise recesses or elevations.

According to at least one embodiment, the semiconductor body is configured to detect radiation, like electromagnetic radiation, with an energy of at least 10 eV. Other than electromagnetic radiation, electron beams or ion beams may also be referred to as the radiation to be detected. For example, the semiconductor body is configured to detect X-rays. By way of example, the semiconductor body is configured to detect radiation with an energy of at least 50 eV or of at least 70 eV and additionally or alternatively of at most 50 keV or of at most 30 keV or of at most 20 keV.

For example, the radiation detector is a silicon drift detector, SDD for short.

According to at least one embodiment, the first main side includes a radiation entrance area for the radiation. For example, the semiconductor body is configured to detect the radiation only or predominantly in a region covered by the entrance area. For example, the entrance area is defined by a cathode contact provided as a ring around the entrance area and being in electric contact with the semiconductor body.

According to at least one embodiment, the method comprises the step of generating a bottom insulation layer at the first main side. As an option, the bottom insulation layer is generated directly at the first main side. The bottom insulation layer comprises or consists of one or a plurality of first electrically insulating materials.

Although referred to as ‘layer’, the bottom insulation layer may either be a single, homogeneous layer of just one material, or the bottom insulation layer is indeed a layer stack of at least two different sub-layers, or the bottom insulation layer comprises a structuring including different adjacent materials and seen in top view of the entrance region. The same may apply for all other components of the radiation detector designated as a layer.

According to at least one embodiment, the method comprises the step of applying a sacrificial layer on the bottom insulation layer, for example, directly on the bottom insulation layer. The sacrificial layer may be applied all over the first main side and may then be limited to a spacer region including the entrance area, or the sacrificial layer may be immediately applied only in the spacer region. The spacer region may protrude from the entrance area, seen in top view, for example, by at most 50% or by at most 25% or by at most 10% of a fraction of a mean diameter of the entrance window. The mean diameter D of the entrance window is the square root of four times of an area content A of the entrance area divided by π, that is, D=(4 A/π)0.5. Especially, the sacrificial layer is applied directly on the bottom insulation layer throughout the spacer region, including the radiation entrance area.

According to at least one embodiment, the method comprises the step of applying a reinforcing layer over the bottom insulation layer and over the sacrificial layer. The reinforcing layer may be applied directly on the bottom insulation layer, especially outside the spacer region. Within the spacer region, the reinforcing layer may be applied directly on the sacrificial layer.

It is possible that the reinforcing layer is applied as a continuous layer without any holes. Thus, the sacrificial layer may be sandwiched between the bottom insulation layer and the reinforcing layer. At an edge of the sacrificial layer, the reinforcing layer may comprise a step or a ramp. The reinforcing layer comprises or consists of one or a plurality of second electrically insulating materials. The at least one second electrically insulating material may be different from the at least one first electrically insulating material, or these materials may be the same.

According to at least one embodiment, the method comprises the step of exposing the bottom insulation layer from the sacrificial layer and also from the reinforcing layer. This step is carried out at least in the entrance area so that the entrance area is freed from the sacrificial layer and the reinforcing layer. In this method step, a thickness of the bottom insulation layer may not be affected, that is, the thickness of the bottom insulation layer after the exposing step may be the same as before the exposing step. This applies, for example, with a tolerance of at most 10% or of at most 4% or of at most 1% of the thickness of the bottom insulation layer before the exposing step.

According to at least one embodiment, the bottom insulation layer and the reinforcing layer remain directly on top of each other in one or a plurality of insulation regions of the first main side outside the entrance area. That is, there is at least one location outside the entrance area, for example, outside the spacer region, where the bottom insulation layer and the reinforcing layer are still present in the finished radiation detector.

In at least one embodiment, the method is for producing a radiation detector and comprises the following steps, for example, in the stated order:
providing a semiconductor body with a first main side and an opposite, second main side, wherein the semiconductor body is configured to detect radiation with an energy of at least 10 eV and the first main side includes a radiation entrance area for the radiation;
generating a bottom insulation layer directly at the first main side, the bottom insulation layer comprising a first electrically insulating material;
applying a sacrificial layer directly on the bottom insulation layer across the entrance area so that throughout the entrance area the bottom insulation layer is between the semiconductor body and the sacrificial layer; and
exposing the bottom insulation layer from the sacrificial layer in the entrance area, wherein the bottom insulation layer remains in at least one insulation region of the first main side outside the entrance area.

In at least one embodiment, the method is for producing a radiation detector and comprises the following steps, for example, in the stated order:
providing a semiconductor body with a first main side and an opposite, second main side, wherein the semiconductor body is configured to detect radiation with an energy of at least 10 eV and the first main side includes a radiation entrance area for the radiation;
generating a bottom insulation layer directly at the first main side, the bottom insulation layer comprising a first electrically insulating material;
applying a sacrificial layer directly on the bottom insulation layer across the entrance area so that throughout the entrance area the bottom insulation layer is between the semiconductor body and the sacrificial layer;
applying a reinforcing layer over the bottom insulation layer so that the sacrificial layer is sandwiched between the bottom insulation layer and the reinforcing layer, the reinforcing layer comprising a second electrically insulating material; and
exposing the bottom insulation layer from the sacrificial layer and from the reinforcing layer in the entrance area, wherein the bottom insulation layer and the reinforcing layer remain directly on top of each other in at least one insulation region of the first main side outside the entrance area.

Radiation detectors, like SDDs, are sold in growing numbers. However, larger quantities require more automatization of the manufacturing processes of such detectors. In conventional SDDs, machine-processing of the devices can cause scratches on a surface, especially due to exposed metallizations. Such defects may lead to inoperable devices or may hamper performance. Moreover, such exposed surfaces of the detectors may be contaminated by particles, metals or humidity, leading to corrosion, so that the operability and performance of the devices may also be negatively influenced.

With the method described herein, degeneration and damage of the most sensitive parts of the detectors can be avoided, and automatization can be expanded. This is achieved, inter alia, by applying the bottom insulation layer and, optionally, the reinforcing layer and by using the sacrificial layer to protect the entrance area during processing of the optional reinforcing layer so that no thinning of the bottom insulation layer is required. Furthermore, by using an additional protection layer, metal contacts, like metal layers, can be located in recesses so that scratches and damage to more sensitive components can be avoided.

According to at least one embodiment, the first electrically insulating material is an oxide. For example, one constituent of said oxide is also a constituent of the semiconductor body. That is, the first electrically insulating material and the semiconductor body share the same chemical element. For example, if the semiconductor body is comprised of silicon, then the oxide is a silicon oxide, like SiO₂₋ₓ. For example, x is a real number between −0.3 and +0.3, inclusive. That is, the silicon oxide can be, but does not need to be, stoichiometric SiO₂.

According to at least one embodiment, the bottom insulation layer is generated by oxidation, such as thermal oxidation, of the semiconductor body. This is done, for example, at a temperature of at least 800° C. or of at least 950° C. Alternatively or additionally, said temperature is at most 1500° C. or 1200° C. It is possible that the first main side is formed by said oxidation.

According to at least one embodiment, the bottom insulation layer is generated with a constant thickness all over the first main side of the semiconductor body. Hence, thickness variations of the bottom insulation layer across the semiconductor body may be at most 5% or at most 1% or at most two monolayers or at most one monolayer of the first electrically insulating material. Such a constant thickness is enabled because the bottom insulation layer is used as grown so that no subsequent thinning of the bottom insulation layer is carried out in regions in which the bottom insulation layer remains on the first main side.

According to at least one embodiment, a final thickness of the bottom insulation layer in the entrance area, after exposing the bottom insulation layer from the sacrificial layer and from the reinforcing layer, is the same or nearly the same as a thickness of the bottom insulation layer immediately after generating the bottom insulation layer. Hence, the exposing step does not, or does not significantly, affect the thickness of the bottom insulation layer. This applies, for example, with a tolerance of at most 5% or at most 1% or at most two monolayers or at most one monolayer of the thickness of the bottom insulation layer prior to the exposing step.

According to at least one embodiment, the method further comprises the step of forming a cathode region in the semiconductor body. For example, the cathode region is p-doped, such as p⁺-doped. This means, for example, that a maximum doping concentration in the cathode region is at least 10¹⁹ cm⁻³ or is at least 10²⁰ cm⁻³ and/or is at most 10²¹ cm⁻³.

According to at least one embodiment, the cathode region is located at the first main side next to the entrance area, for example, directly at the first main side. The cathode region may extend continuously and uninterrupted throughout the cathode region. Across the entrance area, the cathode region may be of constant thickness. At an edge or near an edge of the cathode region and/or of the entrance area, the cathode region may have a sub-region with increased thickness. Said sub-region may be of annular shape, seen in top view of the entrance region.

According to at least one embodiment, the cathode region is doped by ion implantation. Said doping is done, for example, through the bottom insulation layer. Further, said doping may be done prior to application of the sacrificial layer. Thus, the only layer through which said doping is done may be the bottom insulation layer.

According to at least one embodiment, the exposing of the bottom insulation layer from the sacrificial layer and from the reinforcing layer in the entrance area comprises:
removing the reinforcing layer by means of a first etching method, and
subsequently removing the sacrificial layer by means of a second etching method, the second etching method selectively etching the sacrificial layer relative to the bottom insulation layer.

The term ‘selectively’ may mean a difference in an etching rate of the sacrificial layer and the bottom insulation layer of at least two or of at least ten or of at least 20. The etching rate of the sacrificial layer is the higher one. For example, the first etching method is a dry chemical etching and the second etching method is a wet chemical etching.

According to at least one embodiment, the exposing of the bottom insulation layer from the sacrificial layer and from the reinforcing layer in the entrance area comprises:
seen in top view of the entrance area, forming a spacer line from the sacrificial layer around the entrance area.

For example, the spacer line is a continuous, closed line around the entrance area in the finished detector. The spacer line may be of annular shape and/or may form a frame around the entrance area. It is possible that the spacer line limits the entrance area in a lateral direction. That is, the entrance area can be an area surrounded by and located within the spacer line.

According to at least one embodiment, a width of the spacer line is at most 50% or is at most 25% or is at most 10% of the mean diameter of the entrance area enclosed by the spacer line, seen in top view of the entrance area. Said width is, for example, at least 1% or at least 2% or at least 5% of the mean diameter.

According to at least one embodiment, the method comprises forming a cathode contact. The cathode contact may provide electric contact with the cathode region. The cathode contact may run completely through the bottom insulation layer and through the reinforcing layer.

For example, the cathode contact is of an alloy and/or is a metallic contact. For example, the cathode contact is of an aluminum alloy, like Alsip. The same may apply for the other electric contacts of the radiation detector.

According to at least one embodiment, seen in top view of the entrance area, the spacer line is completely surrounded by the cathode contact. That is, there is some distance between the entrance area and the cathode contact due to the spacer layer. The spacer line, and thus the sacrificial layer, may be of an electrically conductive material. The cathode contact may be distant from the spacer line so that the cathode contact and the spacer line do not touch and are electrically separated from each other. For example, the cathode contact completely surrounds the spacer layer and/or the entrance area.

According to at least one embodiment, the method further comprises:
applying a protection layer on top of the reinforcing layer.
The protection layer can be applied on the first main side or on the second main side or on the first and the second main side.

For example, the protection layer is applied directly on the reinforcing layer. It is possible that the protection layer partially covers the electric contacts of the radiation detector, such as the cathode contact. That is, the protection layer can be in direct contact with the electric contacts and may bury parts of the electric contacts. For example, the protection layer protrudes over all electric contacts, in a direction away from the respective main side of the semiconductor body. Thus, a thickness of the radiation detector may be defined by the protection layer.

According to at least one embodiment, the exposing the bottom insulation layer from the sacrificial layer and from the reinforcing layer includes exposing the bottom insulation layer from the protection layer.

According to at least one embodiment, a plurality of holes are formed through the protection layer. The holes may be formed outside the entrance area only. The holes can be used for electrically contacting the semiconductor body. Thus, the holes may be configured for bonding wires or the like.

According to at least one embodiment, the protection layer and/or the reinforcing layer is of a nitride. For example, the protection layer is produced by plasma enhanced chemical vapor deposition, PECVD for short. The reinforcing layer may be produced by low pressure chemical vapor deposition, LPCVD for short. For example, the protection layer and/or the reinforcing layer is of a nitride, like Si₃N₄ or a non-stoichiometric silicon nitride. However, the protection layer and/or the reinforcing layer may also be of an oxide of a metal or a semiconductor element, like an aluminum oxide or a silicon oxide. The protection layer and the reinforcing layer may be of the same material or may be of different materials or material compositions.

According to at least one embodiment, the semiconductor body is of n-doped Si. For example, a maximum doping concentration of the n-doping of the semiconductor body is at least 10¹⁶ cm⁻³ or is at least 10¹⁷ cm⁻³ and/or is at most 10¹⁹ cm⁻³.

Regions of the semiconductor body with a different doping, like p-doping, p⁺-doping or n⁺-doping, may be formed in the semiconductor body by means of an additional doping method, such as ion implantation.

According to at least one embodiment, the sacrificial layer, and thus the spacer line, comprises a semiconductor material, like silicon. For example, the sacrificial layer and the spacer line are of poly-Si or amorphous silicon.

According to at least one embodiment, a thickness of the bottom insulation layer, as generated, is at least 10 nm or is at least 0.03 μm and/or is at most 0.25 μm or is at most 0.15 μm. For example, said thickness is between 60 nm and 90 nm inclusive.

According to at least one embodiment, a thickness of the reinforcing layer, as applied, is at least 1 nm or is at least 0.05 μm or is at least 80 nm and/or is at most 0.3 μm or is at most 0.2 μm or is at most 100 nm. For example, said thickness is between 70 nm and 130 nm inclusive. It is possible that the thickness of the reinforcing layer is larger than the thickness of the bottom insulation layer, as generated. Said thicknesses may differ at least by a factor of 1.1 or by a factor of 1.2 and/or at most by a factor of 5 or by a factor of 2.

According to at least one embodiment, a thickness of the sacrificial layer, as applied, is at least 1 nm or is at least 0.1 μm and/or is at most 2 μm or at most 0.5 μm. For example, said thickness is between 150 nm and 300 nm inclusive.

According to at least one embodiment, the method further comprises:
forming at least one first guard ring contact region which is in the semiconductor body at the first main side.

For example, the at least one first guard ring contact region is p⁺-doped. It is possible that the at least one first guard ring contact region is formed in the same ion implantation step as the contact region. However, the at least one first guard ring contact region may be doped by implanting ions directly into the semiconductor body, that is, not through the bottom insulator layer. Preferably, there is a plurality of the first guard ring contact regions, for example, at least two and/or at least eight of the first guard ring contact regions.

According to at least one embodiment, the at least one first guard ring contact region runs around and distant from the entrance window, seen in top view of the entrance window, for example, completely around the entrance window. The at least one first guard ring contact region may be of annular shape. For example, the at least one first guard ring contact region is electrically contacted by a first guard contact running through the bottom insulation layer and the reinforcing layer.

According to at least one embodiment, the bottom insulation layer and the reinforcing layer are also generated on the second main side. It is possible that these layers are simultaneously formed on the first and on the second main side in the same method steps, respectively. It is possible that these layers have the same thicknesses on the second main side as on the first main side, respectively.

According to at least one embodiment, the method further comprises:
forming a plurality of drift ring contact regions in the semiconductor body at the second main side.

For example, the drift ring contact regions are p⁺-doped. It is possible that the drift ring contact regions are formed with the same parameters as the cathode region. The drift ring contact regions may be generated by ion implantation, wherein said ion implantation may be performed in places through the bottom insulation layer at the second main side and may be performed in places directly onto the second main side.

According to at least one embodiment, the method further comprises:
forming an anode contact region in the semiconductor body at the second main side.

For example, the anode contact region is n⁺-doped. That is, a maximum doping concentration in the anode contact region may be at least 10¹⁹ cm⁻³ or at least 10²⁰ cm⁻³ and/or may be at most 1021 cm⁻³.

According to at least one embodiment, the drift ring contact regions run around and distant from the anode contact region. It is possible that the drift ring contact regions are arranged in a concentric manner around the anode contact region and/or are of annular shape. The drift ring contact regions may be arranged in an equidistant manner, or a distance between adjacent drift ring contact regions may change in a radial direction away from the anode contact region. Seen in top view of the second main side, the drift ring contact regions may be located between the anode contact region and at least one second guard ring contact region.

According to at least one embodiment, the anode contact region and all or some of the drift ring contact regions overlap with the entrance window, seen in top view of the entrance window. That is, the anode contact region and at least some of the drift ring contact regions are located below the cathode region. The anode contact region may be located in a center of the entrance area, seen in top view.

Analogously to the first main side, the protection layer can be provided at the second main side so that at the second main side there can be the insulation layer, the reinforcing layer and the protection layer, in the stated sequence.

A radiation detector is additionally provided. The radiation detector may be produced by means of the method described in connection with at least one of the above-stated embodiments. Features of the radiation detector are therefore also disclosed for the method and vice versa.

In at least one embodiment, the radiation detector is configured to detect radiation with an energy of at least 10 eV and comprises:
an n-doped semiconductor body with a first main side and an opposite second main side;
a radiation entrance area for the radiation at the first main side, the semiconductor body being provided with a cathode region which is p⁺-doped at the radiation entrance area;
a bottom insulation layer which comprises a first electrically insulating material directly at the first main side; and
a cathode contact running through the bottom insulation layer and electrically contacting the cathode region outside the entrance area,
wherein the bottom insulation layer completely covers the entrance area; and
wherein there is at least one insulation region of the first main side outside the entrance area and the bottom insulation layer has the same thickness both in the entrance area and in the at least one insulation region.

In at least one embodiment, the radiation detector is configured to detect radiation with an energy of at least 10 eV and comprises:
an n-doped semiconductor body with a first main side and an opposite second main side;
a radiation entrance area for the radiation at the first main side, the semiconductor body being provided with a cathode region which is p⁺-doped at the radiation entrance area;
a bottom insulation layer which comprises a first electrically insulating material directly at the first main side;
   a reinforcing layer at places directly on the bottom insulation layer and comprising a second electrically insulating material; and
   a cathode contact running through the bottom insulation layer and the reinforcing layer and electrically contacting the cathode region outside the entrance area,
   wherein the bottom insulation layer completely covers the entrance area and the entrance area is free of the reinforcing layer; and
   wherein there is at least one insulation region of the first main side outside the entrance area in which the reinforcing layer is directly on the bottom insulation layer and the bottom insulation layer has the same thickness both in the entrance area and in the at least one insulation region.

The radiation detector may further comprise the spacer line on the first main side around the entrance area, seen in top view.

According to at least one embodiment, the radiation detector further comprises a collimator. For example, the collimator is applied on the first main side outside the entrance area, seen in top view. It is possible that the collimator is of one or a plurality of metals and/or semiconductor materials. The semiconductor body is shielded from radiation outside the entrance area by means of the collimator. Hence, the first main side can be reached by the radiation in the entrance area only, as other parts of the first main side are blocked by the collimator.

According to at least one embodiment, the collimator is attached to the semiconductor body by means of an adhesive, like a glue.

According to at least one embodiment, the reinforcing layer and the protection layer are located between the semiconductor body and the adhesive and optionally also the bottom insulator layer.

### BRIEF DESCRIPTION OF THE DRAWINGS

A method and a radiation detector described herein are explained in greater detail below by way of exemplary embodiments with reference to the drawings. Elements which are the same in the individual figures are indicated with the same reference numerals. The relationships between the elements are not shown to scale, however, but rather individual elements may be shown exaggeratedly large to assist in understanding.

FIG. 1 shows a schematic block diagram of an exemplary embodiment of a method described herein;

FIGS. 2 to 5 show schematic sectional views of method steps of an exemplary embodiment of a method described herein;

FIGS. 6 to 9 show schematic sectional views of exemplary embodiments of radiation detectors described herein;

FIG. 10 shows a schematic sectional perspective view of a modified radiation detector useful for understanding exemplary embodiments of radiation detectors described herein;

FIGS. 11 and 12 show schematic sectional views of exemplary embodiments of radiation detectors described herein; and

FIGS. 13 to 16 show schematic top views of exemplary embodiments of radiation detectors described herein.

### DETAILED DESCRIPTION OF ILLUSTRATIVE EMBODIMENTS

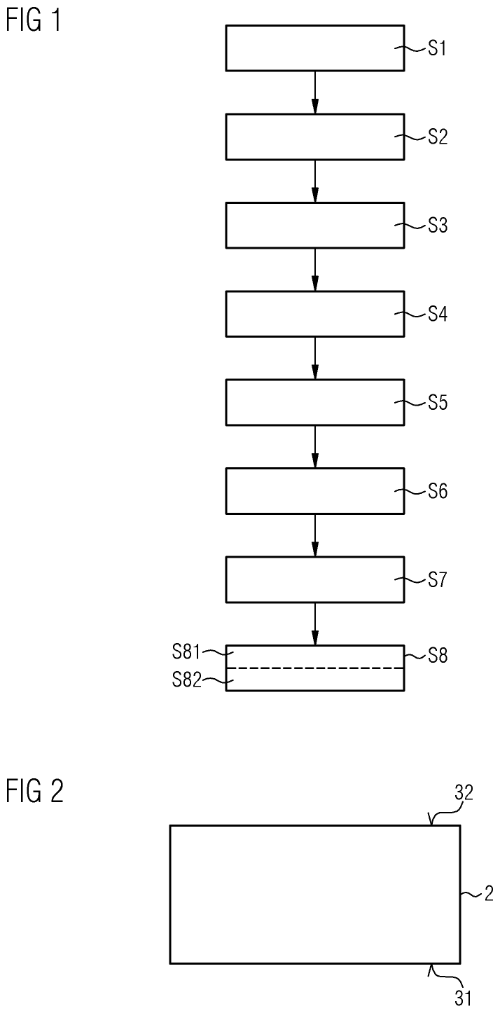

FIG. 1 shows a schematic block diagram of a manufacturing method of a radiation detector 1 described herein. The method steps are explained in more detail below in connection with FIGS. 2 to 5.

In an embodiment, the method for producing the radiation detector 1 may comprise the following steps:
S1: Providing the semiconductor body 2 with a first main side 31, wherein the semiconductor body 2 is for detecting radiation R with an energy of at least 10 eV;
S2: Generating a bottom insulation layer 41 directly at the first main side 31;
S4: Applying a sacrificial layer 42 directly on the bottom insulation layer 41 across an entrance area 33 for the radiation R;
As an option, S5: Applying a reinforcing layer 43 over the bottom insulation layer 41; and
S8: Exposing the bottom insulation layer 41 from the sacrificial layer 42 and, if previously applied, the reinforcing layer 43 in the entrance area 33, wherein the bottom insulation layer 41 and the reinforcing layer 43 remain directly on top of each other in at least one insulation region on the first main side 31 outside the entrance area 33.

For example, the radiation detector 1 is a SDD. The entrance area 33 may be circular. For example, the entrance area 33 is at least 1 mm² or is at least 10 mm² and/or is at most 300 mm².

Thus, in the first method step S1, see also FIG. 2, the semiconductor body 2 is provided which comprises the first main side 31 and the second main side 32. For example, the semiconductor body 2 is an n-doped silicon body. A thickness of the semiconductor body 2 may be at least 0.2 mm and/or at most 2 mm. Seen in top view onto the first main side 31, the silicon body may be polygonal or may be round in shape, like rectangular, square, oval, ellipsoid, circular, or droplet-shaped. Other than illustrated below, it is possible that the method is carried out in a wafer assembly.

In the subsequent method step S2, the bottom insulation layer 41 is generated. This is done, for example, by thermal oxidation. This oxidation may be carried out, for example, at a temperature of around 1100° C. The resulting bottom insulation layer 41 can be of a silicon dioxide, either stoichiometric or non-stoichiometric. A resulting thickness of the bottom insulation layer 41 may be around 70 nm, for example. The resulting bottom insulation layer 41 is of constant or nearly constant thickness.

Simultaneously, it is possible that the bottom insulation layer 41 is generated on the second main side 32 in the same manner.

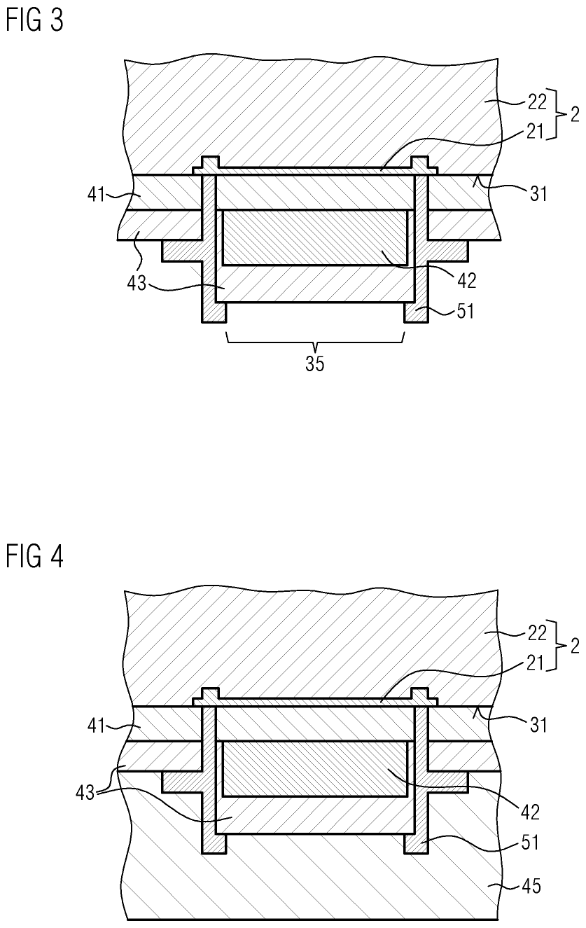

Then, an optional method step S3 can be carried out, see FIG. 3. In step S3, a cathode region 21 is produced by p⁺ doping. This is done, for example, by means of ion implantation through the cathode region. A remaining base body 22 of the semiconductor body 2, outside the cathode region 21, is weakly n-doped.

In a further option it is possible to have an increased thickness of the cathode region 21 at an edge of and around a spacer region 35, either by structuring the mask layer, by adapting an ion energy during implantation or by forming holes in the bottom insulation layer 41. The spacer region 35 is an area in which the sacrificial layer 42 is subsequently applied. It is possible that the region with increased thickness of the cathode region 21 is close to, but not exactly at, an outer edge of the cathode region 21. The cathode region 21 is essentially limited to the spacer region 35; that is, the cathode region 21 may protrude from the spacer region 35 in a direction parallel with the first main side 31 for at most 25% or for at most 15% or for at most 5% of a mean diameter of the spacer region 35.

Thus, in the method step S4 the sacrificial layer 42 is directly applied on the bottom insulation layer 41 and defines the spacer region 35. For example, the sacrificial layer 42 is of poly-Si. A thickness of the sacrificial layer 42 may be 0.2 μm. A material for the sacrificial layer 42 can either be applied on the whole first main side 31 and can then be removed to remain only in the spacer region 35, or the material for the sacrificial layer 42 is applied only in the spacer region 35, for example, by using a further mask layer, not shown.

Afterwards, still see FIG. 3, in optional method step S5 the reinforcing layer 43 is applied directly on the bottom insulation layer 41 as well as directly on the sacrificial layer 42. For example, the reinforcing layer 43 is of silicon nitride, either stoichiometric or non-stoichiometric. A thickness of the reinforcing layer 43 is, for example, 90 nm. The reinforcing layer 43 may completely cover side faces of the sacrificial layer 42 running oblique with the first main side 31. The reinforcing layer 43 may be produced with LPCVD.

Simultaneously, it is possible that the reinforcing layer 43 is generated on the second main side 32 in the same manner.

In the optional method step S6, also illustrated in connection with FIG. 3, an electric cathode contact 51 is formed. This is done by forming at least one contact hole, for example, such as an annular ring, through the bottom insulation layer 41 and the reinforcing layer 43. The at least one contact hole is located, for example, outside the spacer region 35 and possibly outside a region where the reinforcing layer 43 covers the side faces of the sacrificial layer 42. Said at least one contact hole may be congruent with the region of increased thickness of the cathode region 21. Said at least one contact hole is partly or completely filled with an electrically conductive material, for example with a metal or metal alloy such as Alsip. A thickness of the electrically conductive material is, for example, at least 0.2 μm and/or at most 0.9 μm, like 550 nm.

For example, the electrically conductive material for the cathode contact 51 is applied such that a side of the reinforcing layer 43 facing away from the semiconductor body 2 is directly covered adjacent to the at least one contact hole filled with the electrically conductive material. Hence, contact faces can result on top of the reinforcing layer 43, especially outside the spacer region 35.

The electrically conductive material in the at least one contact hole is separated from the sacrificial layer 42 by means of the reinforcing layer 43. The resulting structure is shown in FIG. 3.

In the subsequent optional method step S7, see FIG. 4, a protection layer 45 is applied all over the first main side 31 and, optionally, over the second main side 32 as well. That is, the protection layer 45 directly covers the reinforcing layer 43 outside and in the spacer region 35 as well as the cathode contact 51. For example, the protection layer 45 is made of silicon nitride, either stoichiometric or non-stoichiometric.

A thickness of the protection layer 45 is, for example, at least 0.5 um or at least 0.7 μm and/or at most 3 μm or is at most 1.0 μm, such as 850 nm. The protection layer 45 may be produced by PECVD. It is possible that a raised portion, with the sacrificial layer 42, is embedded in the protection layer 45. This may apply for all other examples of the radiation detector 1 as well.

In the method step S8, see FIG. 5, the bottom insulation layer 41 is exposed in the entrance area 33. This is done by removing the optional protection layer 45 as well as forming a hole completely through the reinforcing layer 43 and the sacrificial layer 42. By forming said hole, a spacer line 44 is created that is composed of remaining portions of the sacrificial layer 42. Thus, the spacer line 44 covers the bottom insulation layer 41 in the spacer region 35 minus the entrance area 33. The cathode contact 51 may not be affected by said removal.

In order to access the contact face of the cathode contact 51, at least one contact opening 56 is formed through the protection layer 45. Thus, the contact face is below a surface of the protection layer 45 remote from the semiconductor body 2 and is consequently protected from mechanical damage to said surface. The at least one contact opening 56 can be of annular shape and, thus, may run completely around the entrance area 33.

As an option, method step S8 comprises the sub-steps S81 and S82. In step 81, the reinforcing layer 43 is removed from the entrance area 33. This is done, for example, by dry chemical etching. Then, in step 82, the sacrificial layer 42 is removed from the entrance area 33, for example, by wet chemical etching.

If method step S5 is not done and, thus, there is no reinforcing layer 43, of course method steps S6, S7, S8 and S81 are to be adapted accordingly.

Other than shown in FIG. 5, the sacrificial layer 42 may be completely removed so that no spacer line 42 remains.

Although shown as single layers, as an option at least one of the bottom insulation layer 41, the sacrificial layer 42, the optional reinforcing layer 43, the cathode contact 51 and the protection layer 45 can in principle also be multi-layered.

Accordingly, in one example, the method may be summarized as follows:
In order to improve the homogeneity of a target value of the oxide in the entrance window, that is, of the bottom insulation layer, its final thickness is already defined during thermal oxidation. Here, the homogeneity achieved is typically in the region of 1 nm across a wafer.
The entrance window, that is, the cathode region 21, is then implanted and protected from further processing with the poly-silicon sacrificial layer. This prevents both unwanted thinning by cleaning processes and contamination by, for example, metallization, of the bottom insulation layer.
To improve the electrical breakdown strength of the comparably thin oxide, an LPCVD nitride layer is deposited as the reinforcing layer.
Then, a process is carried out for creating the contact hole openings, and the implantations and the metallization is carried out to create the cathode contact.
Subsequently, a PECVD nitride protection layer is deposited on both sides of the semiconductor body. This now encapsulates all sensitive metal tracks that do not need to be contacted.
In order to electrically contact the semiconductor body, the protection layer is removed from these areas. Similarly, in the entrance window, the protection layer is removed down to the sacrificial layer. The sacrificial layer can now be removed wet-chemically with a high selectivity towards the bottom insulation layer in the entrance window.

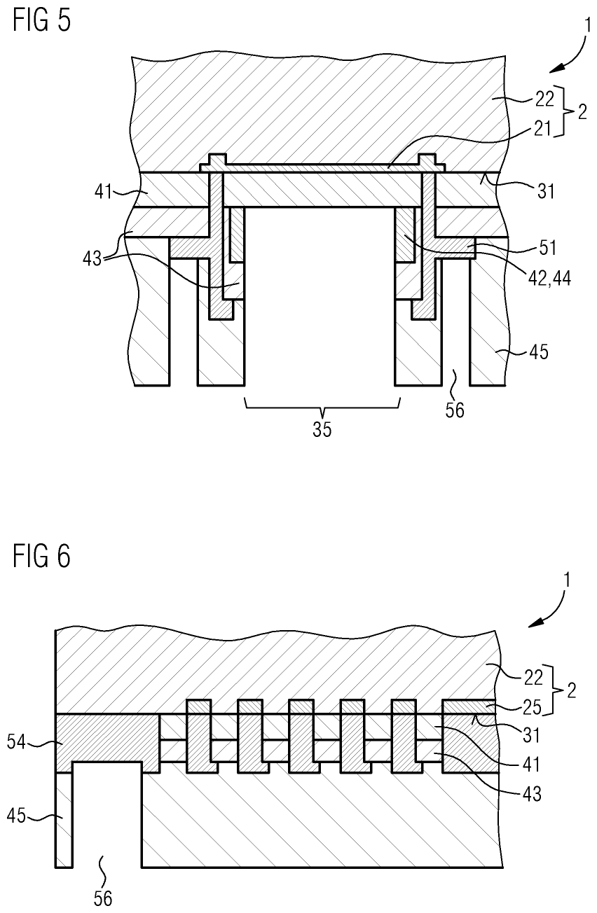

FIGS. 6 to 9 show further regions of the radiation detector 1, an overall picture of a detector can be seen in FIG. 10.

In FIG. 6, it is shown that optionally there are guard rings at the first main side 31. These guard rings are composed of first guard ring contact regions 25 and corresponding first guard contacts 54. The guard rings may run in an annular manner around the cathode contact 51, not shown in FIG. 6.

The first guard ring contact regions 25 may be simultaneously formed with the cathode region 21 and, thus, can be p⁺-doped. The first guard contacts 54 can be simultaneously formed with the cathode contact 51. The first guard ring contact regions 25 are thus located between remaining areas with the bottom insulation layer 41 and the optional reinforcing layer 43. For example, a width of the guard rings is at least 0.1 mm or at least 0.3 mm and/or is at most 2 mm or is at most 0.6 mm.

Accordingly, the same as applies to FIGS. 1 to 5 may also apply to FIG. 6, and vice versa.

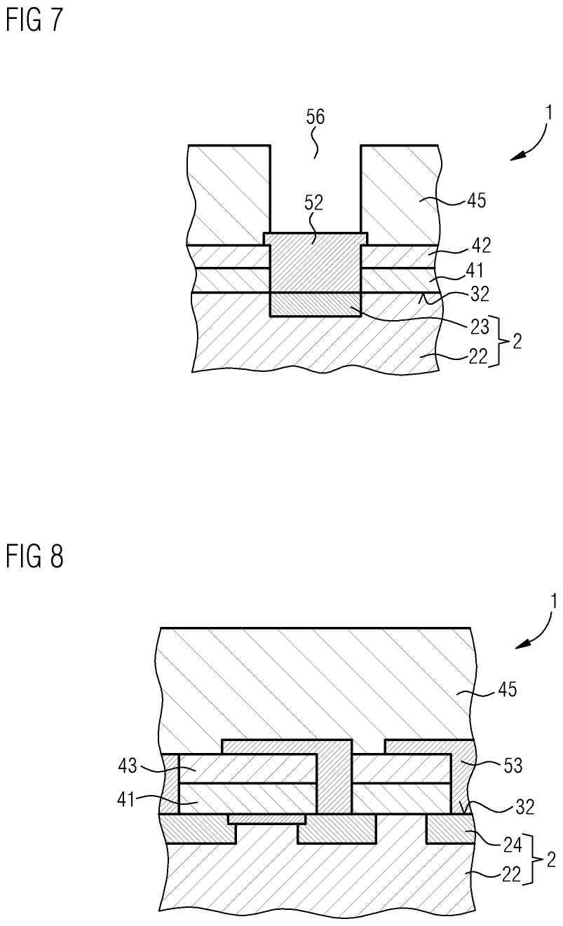

In FIG. 7 it is shown that an anode contact region 23 is formed in a center of the entrance area 33, but located at the second main side 32. The anode contact region 23 is n⁺-doped.

The anode contact region 23 as well as an associated anode contact 52 can be manufactured analogously to the cathode contact 51.

Accordingly, the same as applies to FIGS. 1 to 6 may also apply to FIG. 7, and vice versa.

In FIG. 8 it is shown that drift ring contact regions 24 are formed on the second main side 32. The drift ring contact regions 24 can be p⁺-doped and can be formed analogously to the cathode region 21 and the first guard ring contact regions 25. Drift ring contacts 53 can be manufactured analogously to the cathode contact 51 as well.

It is possible that the drift ring contact regions 24 are shallower beneath the bottom insulation layer 41 and the optional reinforcing layer 43 in order to achieve a desired electric potential profile in the semiconductor body.

Accordingly, the same as applies to FIGS. 1 to 7 may also apply to FIG. 8, and vice versa.

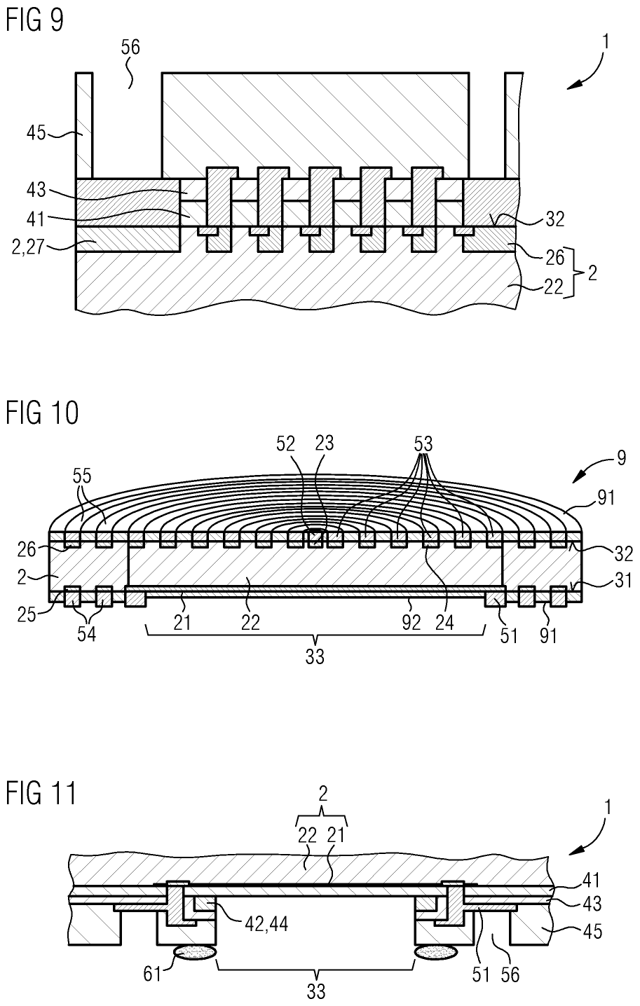

Also, guard rings can be formed at the second main side 32, see FIG. 9. These guard rings are composed of second guard ring contact regions 26 and of second guard contacts 55, analogously to the guard rings on the first main side 31.

As an option, the second guard ring contact regions 26 can have shallow regions like the drift ring contact regions 24, but that are not running completely through remaining portions of the bottom insulation layer 41 and the optional reinforcing layer 43.

As a further option, at an edge of the second main side 32, the semiconductor body 2 may be provided with an edge contact region 27 which is n⁺-doped. The edge contact region 27 can be formed in the same method step and in the same way as the anode contact region 23.

Accordingly, the same as applies to FIGS. 1 to 8 may also apply to FIG. 9, and vice versa.

In FIG. 10 a modified radiation detector 9 is illustrated with just a single insulation layer 91, 92, but no reinforcing layer, no protection layer and no spacer line. Accordingly, there is a thinned insulation layer 92 in the entrance area 33 and consequently a thicker original insulation layer 91 with a thickness as grown. These insulation layers 91, 92 correspond to the bottom insulation layer 41 and are generated by thermal oxidation. Due to the required thinning, the insulation layer 92 may have relatively large thickness variations across the entrance area 33. Contrary to that, the bottom insulation layer 41 can be thin as grown and does not need to be thinned. Further, the electric contacts 51, 52, 53, 54, 55 are exposed on a surface of the detector 9 and can thus be mechanically damaged, for example, by scratching.

Explicitly illustrated for the modified detector 9 only, however, the exemplary embodiments of the radiation detector 1 can all include, individually or in any combination, the guard rings on the first main side, the guard rings on the second main side, the anode contact and the drift ring contacts, in addition to the cathode contact and the associated structure.

Accordingly, the same as applies to FIGS. 1 to 9 may also apply to FIG. 10, and vice versa.

FIGS. 11 to 13 illustrate that the radiation detector 1 further comprises a collimator 60. The collimator 60 has a central opening through which radiation R to be detected can reach the entrance are 33.

To attach the collimator 60, and to ensure some distance between the semiconductor body 2 and the collimator 60, a first adhesive 61, like a glue, may be applied in, for example, 15 points around the entrance area. These points of the first adhesive 61 can be located on the spacer line 44, for example, see FIG. 11. By means of the protection layer 45 the first adhesive 61 can be prevented from contaminating the contact faces of the cathode contact 51, in particular.

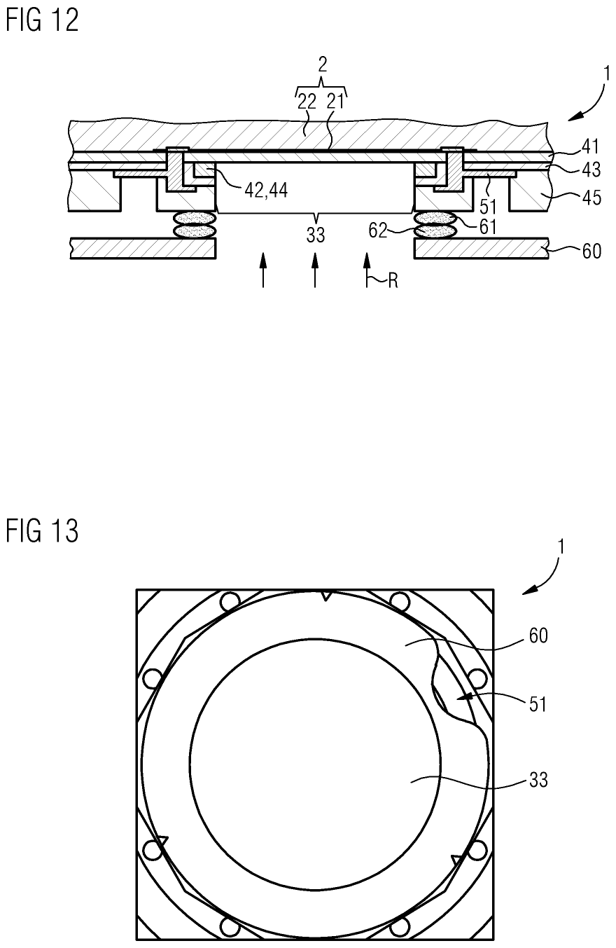

Then, see FIG. 12, a second adhesive 62 is optionally applied. The second adhesive 62 can be applied congruently with the first adhesive 61, that is, also in a point-like fashion. The collimator 60, which may be a multi-layer metal disk, for example, like in U.S. Application No. 2013/037717 A1, is then connected to the semiconductor body 2 by means of the adhesives 61, 62 and covers the semiconductor body 2 outside the entrance area 33. However, because of the protection layer 45, only one of the adhesives 61, 62 may be required. An outer edge of the collimator 60 may be congruent with an outer edge of the semiconductor body 2. Concerning the collimator, the disclosure content of U.S. Application No. 2013/037717 A1 is hereby included by reference herein.

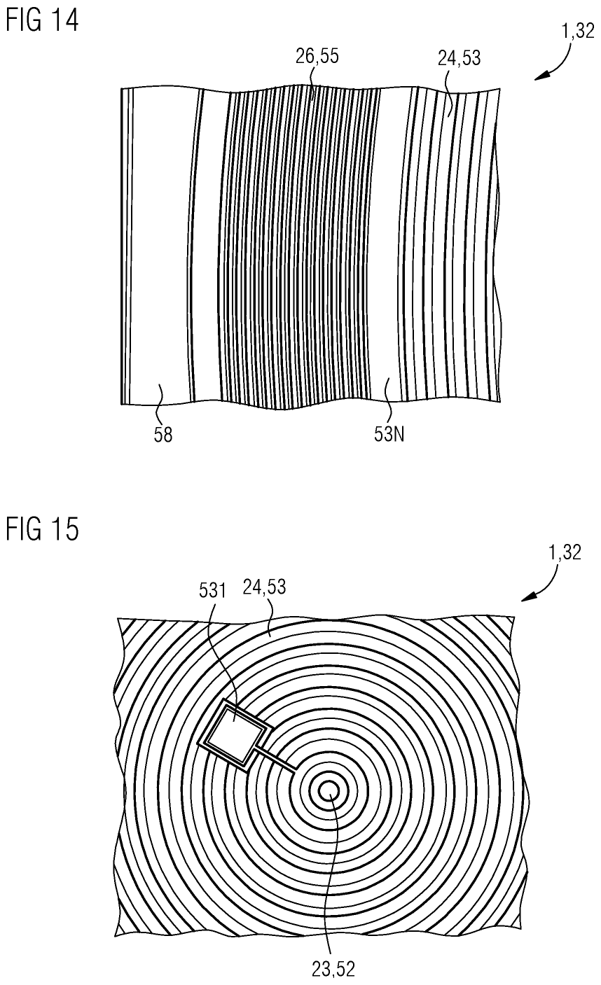

As an option, see FIG. 13, the collimator 60 has a recess for a bond area for the cathode contact 51. Otherwise, the collimator 60 may still completely cover the guard rings, the spacer line 44 and everything in between.

For example, the collimator 60 is annular. That is, the collimator 60 can be a ring, seen in top view. A width of said ring is, for example, at least 0.2 mm and/or at most 3 mm, like 0.6 mm.

Otherwise, the same as applies to FIGS. 1 to 10 may also apply to FIGS. 11 to 13, and vice versa.

In FIGS. 14 to 16, top views of the radiation detector 1 are shown.

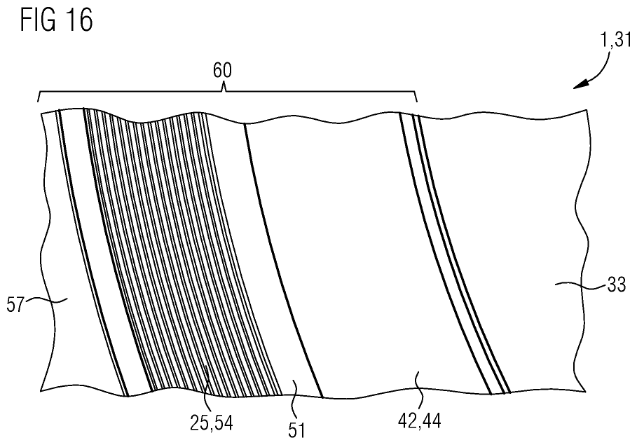

In FIGS. 14 and 15 it can be seen that the anode contact 52 at the second main side 32 is concentrically surrounded by a couple of the drift rings. The anode contact 52 may be a signal contact of the detector 1 to output a measurement signal. An innermost first drift ring contact 531 is close to the anode contact 52 and is provided with a bond pad. An outermost last drift ring contact 53N of the N drift rings is remote from the anode contact 52 and close to the guard rings. A second edge contact 58 may be a ground contact for the guard rings and for the optional edge contact region 27.

FIG. 16 illustrates that, at the first main side 31, there is a first edge contact 57 which is for the guard rings on the top side and which may also be on the ground. The cathode contact 51 can be ring-shaped, seen in top view.

As an option, the protection layer 45 in FIG. 16 is limited to the area between the entrance area 33 and the cathode contact 51.

Otherwise, the same as applies to FIGS. 1 to 13 may also apply to FIGS. 14 to 16, and vice versa.

Hence, without the protection layer 45, the otherwise sensitive outer surface of the radiation detector 1 can be damaged during manual and mechanical assembly of radiation detectors 1, like SDDs, into modules comprising a housing, for example. This leads to a loss of performance or to failure. Further, to mount collimators 60 next to the entrance area 33, an adhesive 61, 62 may need to be applied between the semiconductor body 2 and the collimator 60. Depending on the viscosity of the adhesive 61, 62 and the surface condition of the radiation detector 1, the adhesive 61, 62 can bleed heavily. This can disrupt the performance of the guard rings through static charge and may lead to increased leakage currents. Further, a lateral dimension of the anode contact 52 is very small and makes error-free bonding difficult. Even small inaccuracies in the process flow can lead to de-placement and, thus, to a short circuit. These problems can be avoided by using the protection layer 45.

The passivation of the surface by means of the protection layer 45 also keeps moisture away from the sensitive guard rings. This reduces parasitic surface leakage currents, so that leakage currents in the range of less than 100 pA/cm² at 23° C. can be achieved. When separating the individual radiation detectors 1 manufactured on a wafer level on a saw foil, for example, adhesive residues can remain on the radiation detectors 1, which can promote surface leakage currents without the protection layer 45.

Unless otherwise indicated, the components shown in the figures exemplarily follow directly on top of one another in the specified sequence. Components which are not in contact in the figures are exemplarily spaced apart from one another. If lines are drawn parallel to one another, the corresponding surfaces may be oriented in parallel with one another. Likewise, unless indicated otherwise, the positions of the drawn components relative to one another are correctly reproduced in the figures.

The invention described herein is not restricted by the description on the basis of the exemplary embodiments. Rather, the invention encompasses any new feature and also any combination of features, which includes in particular any combination of features in the patent claims, even if this feature or this combination itself is not explicitly specified in the patent claims or exemplary embodiments.

What is claimed is:

1. A method for producing a radiation detector, the method comprising:
providing a semiconductor body with a first main side and an opposite, second main side, wherein the semiconductor body is configured to detect radiation with an energy of at least 10 eV, and wherein the first main side includes a radiation entrance area for the radiation;
generating a bottom insulation layer located directly at the first main side, the bottom insulation layer comprising a first electrically insulating material;
applying a sacrificial layer directly on the bottom insulation layer across the entrance area so that throughout the entrance area the bottom insulation layer is between the semiconductor body and the sacrificial layer;
applying a reinforcing layer over the bottom insulation layer so that the sacrificial layer is sandwiched between the bottom insulation layer and the reinforcing layer, the reinforcing layer comprising a second electrically insulating material; and
exposing the bottom insulation layer from the sacrificial layer and from the reinforcing layer in the entrance area, wherein the bottom insulation layer and the reinforcing layer remain directly on top of each other in at least one insulation region of the first main side outside the entrance area.

2. The method according to claim 1,
wherein the first electrically insulating material is an oxide, and
wherein the bottom insulation layer is generated by thermal oxidation of the semiconductor body at a temperature of at least 800° C.

3. The method according to claim 1,
wherein the bottom insulation layer is generated with a constant thickness all over the first main side, and
wherein a final thickness of the bottom insulation layer in the entrance area, after exposing the bottom insulation layer from the sacrificial layer and from the reinforcing layer, is the same as a thickness of the bottom insulation layer immediately after generating the bottom insulation layer.

4. The method according to claim 1,
further comprising forming a cathode region, which is p+-doped in the semiconductor body, the cathode region being located at the first main side next to the entrance area,
wherein the cathode region is doped by ion implantation through the bottom insulation layer prior to application of the sacrificial layer.

7. The method according to claim 1, wherein exposing the bottom insulation layer from the sacrificial layer and from the reinforcing layer in the entrance area comprises:
removing the reinforcing layer by a first etching method; and
subsequently removing the sacrificial layer by a second etching method, the second etching method selectively etching the sacrificial layer relative to the bottom insulation layer.

5. The method according to claim 4, wherein exposing the bottom insulation layer from the sacrificial layer and from the reinforcing layer in the entrance area comprises:
seen in top view of the entrance area, forming a spacer line from the sacrificial layer around the entrance area,
wherein a width of the spacer line is at most 25% of a mean diameter of the entrance area enclosed by the spacer line, and
wherein the spacer line is a closed line and is present in a finished radiation detector.

6. The method according to claim 5, wherein, seen in the top view of the entrance area, the spacer line is completely surrounded by a cathode contact which provides electric contact with the cathode region through the bottom insulation layer and through the reinforcing layer.

8. The method according to claim 1,
further comprising:
applying a protection layer on top of the reinforcing layer,
wherein exposing the bottom insulation layer from the sacrificial layer and from the reinforcing layer includes exposing the bottom insulation layer from the protection layer, and
wherein a plurality of holes are formed through the protection layer outside the entrance area for electrically contacting the semiconductor body.

9. The method according to claim 8, wherein the protection layer is of a nitride produced by plasma enhanced chemical vapor deposition.

10. The method according to claim 1,
wherein the semiconductor body is of n-doped Si, and
wherein the reinforcing layer is of a nitride produced by low-pressure chemical vapor deposition.

11. The method according to claim 1,
wherein a thickness of the bottom insulation layer, as generated, is at least 0.03 μm and at most 0.16 μm,
wherein a thickness of the reinforcing layer, as applied, is at least 0.05 μm and at most 0.3 μm and is larger than the thickness of the bottom insulation layer, as generated, and
wherein a thickness of the sacrificial layer, as applied, is at least 0.1 μm and at most 0.6 μm.

12. The method according to claim 1,
further comprising:
forming at least one first guard ring contact region, which is p+-doped in the semiconductor body at the first main side, wherein the at least one first guard ring contact region running around and a distant from an entrance window, seen in top view of the entrance window, and wherein the at least one first guard ring contact region is electrically contacted by a first guard contact running through the bottom insulation layer and the reinforcing layer.

13. The method according to claim 1, wherein the bottom insulation layer and the reinforcing layer are also generated on the second main side with the same thicknesses as on the first main side, respectively.

14. The method according to claim 1,
further comprising:
forming a plurality of drift ring contact regions, which are p+-doped in the semiconductor body at the second main side;
forming an anode contact region which is n+-doped in the semiconductor body at the second main side,
wherein the drift ring contact regions run around and distant from the anode contact region, and
wherein the anode contact region and at least some of the drift ring contact regions overlap with an entrance window, seen in top view of the entrance window.

15. The method according to claim 1, wherein the bottom insulator layer and the reinforcing layer are applied all over the first main side continuously and as closed layers.

16. A radiation detector comprising:
an n-doped semiconductor body with a first main side and an opposite, second main side;
a radiation entrance area for radiation at the first main side, the semiconductor body being comprising a cathode region, which is p+-doped at the radiation entrance area;
a bottom insulation layer, which comprises a first electrically insulating material located directly at the first main side;
a reinforcing layer at places located directly on the bottom insulation layer and comprising a second electrically insulating material; and
a cathode contact running through the bottom insulation layer and the reinforcing layer and electrically contacting the cathode region outside the entrance area,
wherein the bottom insulation layer completely covers the entrance area and the entrance area is free of the reinforcing layer;
wherein at least one insulation region of the first main side is outside the entrance area in which the reinforcing layer is located directly on the bottom insulation layer and the bottom insulation layer has the same thickness both in the entrance area and the at least one insulation region, and
wherein the radiation detector is configured to detect the radiation with an energy of at least 10 eV.

17. The radiation detector according to claim 16, further comprising:
a spacer line on the first main side around the entrance area, seen in top view,
wherein a width of the spacer line is at most 25% of a mean diameter of the entrance area enclosed by the spacer line, and
wherein the spacer line is of silicon and is completely surrounded by the cathode contact.

18. The radiation detector according to claim 16, further comprising:
a collimator applied on the first main side outside the entrance area, seen in top view,
wherein the collimator is attached to the semiconductor body by an adhesive, and
wherein the bottom insulator layer, the reinforcing layer and a protection layer are located between the semiconductor body and the adhesive.

20. A method for producing a radiation detector, the method comprising:
providing a semiconductor body with a first main side and an opposite, second main side, wherein the semiconductor body is configured to detect radiation with an energy of at least 10 eV, and wherein the first main side includes a radiation entrance area for the radiation;
generating a bottom insulation layer located directly at the first main side, the bottom insulation layer comprising a first electrically insulating material;
applying a sacrificial layer directly on the bottom insulation layer across the entrance area so that throughout the entrance area the bottom insulation layer is between the semiconductor body and the sacrificial layer; and
exposing the bottom insulation layer from the sacrificial layer in the entrance area, and
wherein the bottom insulation layer remains in at least one insulation region of the first main side outside the entrance area.
